(19) United States
(12) Patent Application Publication
(10) Pub. No.: US 2023/0399543 A1
(43) Pub. Date: Dec. 14, 2023

(54) CHEMICAL MECHANICAL PLANARIZATION SLURRY AND METHOD OF POLISHING A SUBSTRATE

(71) Applicant: SAINT-GOBAIN CERAMICS & PLASTICS, INC., Worcester, MA (US)

(72) Inventors: Renjie Zhou, Alhambra, CA (US); Stephen Bottiglieri, Easton, PA (US); Lin Fu, Rancho Palos Verdes, CA (US); Chun-Lung Kuan, Anaheim, CA (US)

(21) Appl. No.: 18/332,518

(22) Filed: Jun. 9, 2023

Related U.S. Application Data
(60) Provisional application No. 63/366,212, filed on Jun. 10, 2022.

(51) Int. Cl. C09G 1/02; H01L 21/306

(52) U.S. Cl. CPC C09G 1/02; H01L 21/30625

(57) ABSTRACT

A chemical mechanical polishing (CMP) slurry can comprise a plurality of particles distributed in a carrier, wherein at least a portion of the particles of the plurality of particles can have a body including a core comprising zirconia and a shell overlying at least a portion of the core, wherein the shell comprises silica; an oxidizing agent; and a carrier. The CMP slurry can comprise at least one of a Hydrogen Peroxide Stability % Reduction of not greater than 50%; and a high copper material removal rate.

### CROSS-REFERENCE TO RELATED APPLICATION(S)

This application claims priority under 35 U.S.C. § 119(e) to U.S. Provisional Application No. 63/366,212, entitled “ABRASIVE PARTICLES, COMPOSITION INCLUDING THE ABRASIVE PARTICLES AND METHOD OF USING SAME,” by Lin F U et al., filed Jun. 10, 2022, which is assigned to the current assignee hereof and is incorporated by reference in its entirety.

### BACKGROUND

### Field of the Disclosure

The following is directed to a chemical mechanical polarization (CMP) slurry, and a method of using the CMP slurry for polishing a substrate.

### Description of the Related Art

Compositions for use in material removal operations are known. Such abrasive compositions may include fixed abrasive compositions wherein a collection of abrasive particles are attached to a body or substrate. Alternatively, certain abrasive compositions can include free abrasives, wherein the abrasive particles are not attached to a body or substrate, but are contained within a liquid carrier as a slurry or mixture. Depending upon the type of material removal operation, one may choose to use a fixed abrasive or free abrasive.

Conventional abrasive slurries are most often used in polishing of materials (e.g., glass, metal, etc.). The electronic device manufacturing industry uses polishing slurries for chemical mechanical planarization (CMP). In a typical CMP process, a substrate (e.g., a wafer) is placed in contact with a moving polishing pad, for example, a rotating polishing pad attached to a platen. Additionally, other industries also demand polishing compositions.

### BRIEF DESCRIPTION OF THE DRAWINGS

The present disclosure may be better understood, and its numerous features and advantages made apparent to those skilled in the art by referencing the accompanying drawings.

FIG. 1 includes a cross-sectional illustration of a particulate having a core and a shell according to an embodiment.

FIG. 2 includes a TEM image of a particulate having a core and a shell, which may be used to evaluate the average thickness of the shell.

FIG. 3 includes a plot of H₂O₂ percentages for various samples, some of which include particulates representative of embodiments herein.

FIG. 4 includes a plot of material removal for various samples, some of which include particulates representative of embodiments herein.

### DETAILED DESCRIPTION

The following is directed toward a particulate, or a plurality of particulate particles, including, for example, a plurality of abrasive particles including particulate particles of the embodiments herein. In another embodiment, the particulates may be part of a batch of abrasive particles including the particulate. In still another aspect, a CMP slurry is disclosed that may include the particulate. As used herein, the plurality of particles, batch of abrasive particles, or CMP slurry may include a minority content, majority content or consist of the particulate.

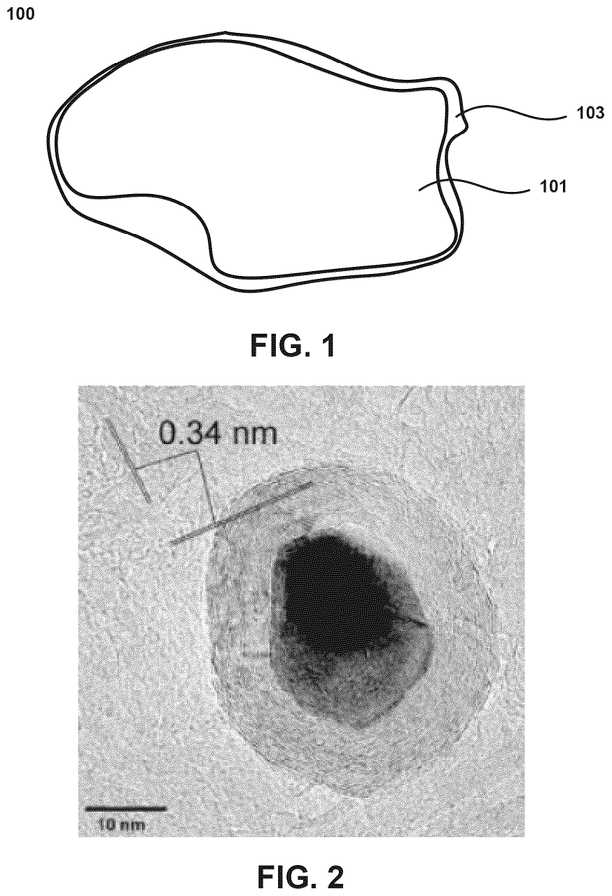

According to one aspect, the particulate may include a core and a shell overlying the core. FIG. 1 includes a cross-sectional illustration of a particulate 100 including a core 101 and a shell 103 overlying at least a portion of the core 101.

FIG. 2 includes a TEM image of a particle having a core and a shell. The image is representative of an image that may be used to measure the average thickness of the shell. A suitable number of similar images can be taken of the particles of the embodiments herein to create a suitable sample data set from which to calculate the average thickness of the shell.

Formation of the particles may include first forming the core. According to one embodiment, a raw material with a zirconium containing material, such as zirconium oxychloride, may be calcined to form zirconia (ZrO₂). After forming a core particulate, the distribution of the core particulate may be controlled using sieving. The sorted core particulate may then be processed to create a shell overlying the core. In one embodiment, the process for forming the shell can include chemical synthesis of a silica-containing material from an organic silicon-containing material (e.g., silane). In one particular embodiment, the formation of the shell layer may include a reaction of a silicon containing precursor, such as silane with other reactants to form a silica-containing shell layer overlying the core. The method for forming the shell may include various techniques, including, for example, but not limited to, sol-gel and co-precipitation process, a TEOS/TMOS process or any process using an organic-containing compound as a precursor, a pickering process, spray-coating, mechano-fusion process, a deposition process (e.g., CVD, ALD, etc.) or any combination thereof. The process for forming the shell may be a process suitable for creating any of the characteristics of the shell as disclosed in any of the embodiments herein. For example, in one non-limiting instance, the process for forming the shell may include a vapor deposition technique for creating a shell having a particular chemistry, morphology and/or thickness. In one particulate embodiment, the process for forming the shell on the core particulate includes using a silicon-containing source, such as an organic silicon source (e.g., TMOS, TEOS). The organic silicon source can be added to water which may cause the release of the silicon material. The core particles may be added to the water and silicon source to create a mixture. The pH of the mixture can be adjusted to control the deposition of the silicon source onto the surface of the core particles, such that a particulate material having a core and shell structure is created.

According to one embodiment, the core may include zirconia and may also include a Cl-containing species. Without wishing to be tied to a particular theory, the Cl-containing species may be particularly beneficial in forming a shell having certain features and/or performance of the particulate. In a particular instance, the core may include a Cl-containing species, such as chlorine as an interstitial or grain boundary material within the zirconia. According to one embodiment, the content of Cl-containing species may be at least 1 ppm, such as at least 5 ppm or at least 10 ppm or at least 20 ppm or at least 50 ppm or at least 75 ppm or at least 100 ppm or at least 125 ppm or at least 150 ppm or at least 200 ppm or at least 300 ppm or at least 400 ppm or at least 500 ppm or at least 600 ppm or at least 700 ppm or at least 800 ppm or at least 900 ppm. Still, in another embodiment, the Cl-containing species may be present in an amount of not greater than 3000 ppm or not greater than 2500 ppm or not greater than 2000 ppm or not greater than 1800 ppm or not greater than 1500 ppm or not greater than 1200 ppm or not greater than 1000 ppm. It will be appreciated that the content of the Cl-containing species may be within a range including any of the minimum and maximum values noted above, including, for example, but not limited to at least 1 ppm and not greater than 3000 ppm or within a range of at least 10 ppm and not greater than 2000 ppm or even within a range including at least 200 ppm and not greater than 1000 ppm.

According to another embodiment, the core may include zirconia. In some instances, the core may include a combination of oxide-containing species, including, for example, but not limited to zirconia, alumina, and the like. Still, in another embodiment, the core may include a particular content of zirconia, such as at least 50 wt % zirconia for a total weight of the core or at least 75 wt % zirconia or at least 80 wt % zirconia or at least 90 wt % zirconia or at least 95 wt % zirconia or at least 98 wt % zirconia or at least 99 wt % zirconia or least 99.5 wt % zirconia for a total weight of the core.

In another embodiment, the core may consist essentially of zirconia, such that some minor content of impurities may exist, but such impurities do not materially impact the performance or characteristics of the core. In still, another non-limiting embodiment, the core consists entirely of zirconia, wherein the total content of non-zirconia species is not greater than 1% or not greater than 0.8% or not greater than 0.5% or not greater than 0.3% or not greater than or not greater than 0.18% or not greater than 0.15%. According to another non-limiting embodiment, the core consists essentially of zirconia and the Cl-containing species. In still another embodiment, the core comprises a polycrystalline abrasive particulate.

In one aspect, the particulate may be part of a plurality of particulates, wherein a minority, a majority or all of the plurality of particulates have the features of the particulate according to an embodiment. In one instance, the particulate may include a core having a D50 within a range of at least 1 nm to not greater than 2000 nm. For example, the core may have a D50 of at least 2 nm or at least 5 nm or at least 10 nm or at least 25 nm or at least 50 nm or at least 75 nm or at least 100 nm or at least 120 nm or at least 140 nm. Still, in another non-limiting embodiment, the core may have a D50 of not greater than 1500 nm or not greater than 1200 nm or not greater than 1000 nm or not greater than 900 nm or not greater than 800 nm or not greater than 700 nm or not greater than 600 nm or not greater than 500 nm or not greater than 400 nm or not greater than 300 nm. It will be appreciated that the core may have a D50 within a range including any of the minimum and maximum values noted above, including, for example, but not limited to within a range of at least 1 nm to not greater than 1500 nm or within a range of at least 2 nm and not greater than 1000 nm or within a range of at least 10 nm to not greater than 500 nm or within a range of at least 20 nm to not greater than 300 nm.

In one aspect, the particle size distribution can be a unimodal or monomodal distribution. As used herein, a distribution is unimodal or monomodal if for some value “m,” it is monotonically increasing for x≤m and monotonically decreasing for x≥m. In that case, the maximum value of f(x) is f(m) and there are no other local maxima.

The particle size distribution features for any of the embodiments herein are measured by laser scattering using a Horiba LA 950. Deionized water is used as a circulation bath medium. A refractive index of 1.66 with an imaginary value of 0.0i is used. The sample is prepared by providing a suitable amount of particulate material into a 50 ml beaker. The beaker is filled to the fill line with a solution of deionized water containing 0.25% to 0.35% sodium hexametaphosphate (SHMP), such that the slurry includes approximately 1-3 wt % solid particulate material in the mixture of deionized water and SHMP. The sample is then sonicated for 30 seconds. The pH of the water is set to 8-10. During the analysis, the sonication function of the Horiba analyzer is on. The sample is pipetted into a circulation bowl at 2 to 3 drops (˜1-3 ml) at a time until the Lamp % is 80-85%. The data from the analysis is imported into suitable computer software capable of providing statistical analysis (e.g., Microsoft Excel). The data analysis functions of the software are used to analyze the distribution specifics.

In another embodiment, a plurality of particles may have a particular particle size distribution that may facilitate improved manufacturing and/or performance. For example, in one embodiment, the core (i.e., uncoated particle) may have a D10-D90 value within a range of at least 1 nm to not greater than 5000 nm. In one particular embodiment, the D10-D90 value can be at least 1 nm or at least 10 nm or at least 25 nm or at least 50 nm or at least 75 nm or at least 100 nm or at least 120 nm or at least 140 nm or at least 260 nm or at least 300 nm or at least 400 nm or at least 500 nm. Still, in another non-limiting embodiment, the D10-D90 value can be not greater than 4500 nm or not greater than 4000 nm or not greater than 3000 nm or not greater than 2000 nm or not greater than 1000 nm or not greater than 800 nm or not greater than 600 nm or not greater than 400 nm or not greater than 200 nm or not greater than 150 nm. It will be appreciated that the D10-D90 value can be within a range including any of the minimum and maximum values noted above, including, for example, but not limited to at least 10 nm to no greater than 3000 nm or within a range of at least 25 nm to not greater than 1000 nm or within a range including at least 50 nm to not greater than 500 nm or even within a range including at least 50 nm to not greater than 150 nm.

In another embodiment, the particulate material or plurality of particulate material (i.e., core and shell) may include D50 of at least 1 nm or at least 2 nm or at least 5 nm or at least 10 nm or at least 25 nm or at least 50 nm or at least 75 nm or at least 100 nm or at least 120 nm or at least 140 nm. Still, in another non-limiting embodiment, the core may have a D50 of not greater than 1500 nm or not greater than 1200 nm or not greater than 1000 nm or not greater than 900 nm or not greater than 800 nm or not greater than 700 nm or not greater than 600 nm or not greater than 500 nm or not greater than 400 nm or not greater than 300 nm. It will be appreciated that the core may have a D50 within a range including any of the minimum and maximum values noted above, including, for example, but not limited to within a range of at least 1 nm to not greater than 1500 nm or within a range of at least 2 nm and not greater than 1000 nm or within a range of at least 10 nm to not greater than 500 nm or within a range of at least 20 nm to not greater than 300 nm.

According to one embodiment, the particulate material may have a particular specific surface area that may facilitate improved manufacturing and/or performance of the particulate. For example, in one embodiment, the core (i.e., uncoated particle) may have a specific surface area within a range of at least 1 m²/g to not greater than 100 m²/g, for example, at least 10 m²/g, or at least 15 m²/g or at least 20 m²/g, and not greater than 80 m²/g, or not greater than 50 m²/g, of not greater than 30 m²/g, or not greater than 25 m²/g.

In one aspect, the shell may be formed to have certain features that facilitate improved performance of the particulate. For example, in one non-limiting embodiment, the average thickness of the shell may be formed to provide a suitable stability with respect to certain oxidizing species while also providing a suitable material removal performance. According to one embodiment, the shell comprises an average thickness of at least 0.5% and not greater than 20% of the median size (D50) of the core. In one non-limiting embodiment, the average thickness of the shell can be at least 0.06% of the D50 of the core, such as at least 0.07% or at least 0.08% or at least 0.09% or at least 0.1% or at least 0.13% or at least 0.15% or at least or at least 0.2% or at least 0.3% or at least 0.4% or at least 0.5% or at least 0.6% or at least 0.7% or at least 0.8% or at least 0.9% or at least 1% or at least 2% or at least 3% or at least 4% or at least 5% of the D50 of the core. Still, in another non-limiting embodiment, the average thickness of the shell can be not greater than 19% of the D50 of the core, such as not greater than 18% or not greater than 17% or not greater than 16% or not greater than 15% or not greater than 14% or not greater than 13% or not greater than 12% or not greater than 11% or not greater than 10% or not greater than 9% or not greater than 8% or not greater than 7% of the D50 of the core. It will be appreciated that the average thickness of the shell can be within a range including any of the minimum and maximum percentages noted above, including, for example, but not limited to at least 0.5% and not greater than 19% of the D50 of the core, or within a range of at least and not greater than 15% of the D50 of the core, or within a range of at least 1% and not greater than 10% of the D50 of the core.

The process of measuring the average thickness of the shell can be conducted by TEM image analysis, such as the image provided in FIG. 2. A plurality of particles is imaged at a suitable magnification to clearly resolve the shell layer, such as a field of view of approximately 100 nm. Ten pictures at the same magnification are taken of randomly selected particles or portions of particles. A statistically relevant sample set is created by taking a suitable number of measurements from the images (e.g., 4 measurements for any shell for at least 10 different particles making 40 total measurements). Image analysis software, such as ImageJ, can be used to evaluate the average thickness of the layer. The average shell thickness is calculated as the average from all of the shell thickness measurements made. The average shell thickness value is then compared to the D50 of the core to calculate the average thickness of the shell as a percentage of the core D50.

Reference herein to any average value may refer to an average value from a single particle, an average value of a plurality of particulates or a batch of abrasive particles or particulates from a CMP slurry. The measurements necessary to determine an average value should be taken from a statistically relevant sample size.

According to another embodiment, the shell layer may include a certain content of silica-containing species, herein also called “SiOx.” In certain aspects, the silica-containing species can include a silane, or silane-containing compounds. In a particular aspect, the silica-containing species consists essentially of silica (SiO₂). As used herein consisting essentially of silica means that at least 99 wt % of the shell layer based on the total weight of the shell is silica.

In one embodiment, the shell layer may include multiple films, including, for example, a first film that is in direct contact with the outer surface of the core, and such a first film may include silica. In another embodiment, the shell layer may include a second film overlying at least a portion of the first film, such that at least a portion of the first film is disposed between the core and the second film. In one instance, the second film may include silane or a silane-containing species.

In another embodiment, the shell may have a particular composition that may facilitate improved performance. For example, in one embodiment, the shell may include at least 90 vol % SiOx for a total volume of the shell, such as at least 95 vol % SiOx or at least 98 vol % SiOx. In one particular embodiment, the shell may consist essentially of SiOx such that impurities may exist in minor contents that do not materially change the characteristics or properties of the shell. In another embodiment, the shell may consist entirely of SiOx. Such percentages may also be average percentages for a plurality or batch of abrasive particles.

In another embodiment, the shell may include a certain content of species that may be considered impurities. Examples of such impurity species may include silicon carbide, diamond, cubic boron nitride, boron carbide, ceria, titania, yttria, rare earth oxides, aluminosilicates, transition metals, transition metal oxides, oxides (e.g., alumina or transitional aluminas), sulfates (e.g., transition metal sulfates), nitrates (e.g., transition metal nitrates) or any combination thereof.

According to one embodiment, the content of such impurity species may be not greater than 9 wt % for a total volume of the shell, such as not greater than 7 wt % impurities or not greater than 5 wt % impurities or not greater than 2 wt % impurities or not greater than 1 wt % impurities or not greater than 0.5 wt % impurities. In one non-limiting embodiment, the shell may include at least 0.001 wt % impurities. The impurities in the shell may be within a range including any of the minimum and maximum percentages noted above. Such percentages may also be average percentages for a plurality or batch of abrasive particles.

In reference to another aspect of a particulate, in some instances, the particulate may have a certain percentage of the core that is covered by the shell, which may facilitate improved performance of the particulate. For example, in one embodiment, the shell may be overlying at least 50% of the total surface area of the core, such as or at least 60% or at least 70% or at least 80% or at least 90% or at least 95% or at least 99%. In one particular embodiment, the shell may be a thin conformal coating overlying essentially the entire core. Such percentages may also be average percentages for a plurality or batch of abrasive particles.

In another embodiment, the shell may have a particular thickness that may facilitate improved manufacturing and/or performance of the particulate. For example, in one embodiment, the shell may have an average thickness of at least 0.1 nm and not greater than 50 nm. In another embodiment, the shell may have an average thickness of at least 0.5 nm or at least 0.8 nm or least 1 nm or at least 1.5 nm or at least 2 nm or at least 3 nm or at least 4 nm or at least 5 nm. In another non-limiting embodiment, the shell may have an average thickness of not greater than 45 nm or not greater than 40 nm or not greater than 35 nm or not greater than 30 nm or not greater than 25 nm or not greater than 20 nm or not greater than 18 nm or not greater than nm or not greater than 14 nm or not greater than 13 nm or not greater than 12 nm. It will be appreciated that the shell may have an average thickness within a range including any of the minimum and maximum values noted above, including, for example, but not limited to at least nm and not greater than 30 nm or at least 0.5 nm and not greater than 20 nm.

In a particular aspect, the average (D50) particle size of the particles can be from 150 nm to 250 nm, and a thickness of the shell may be from 4 nm to 20 nm, or from 6 nm to 15 nm.

According to one embodiment, the particulate material may have a density within a range of at least 3 g/cm³ to not greater than 7 g/cm³. In one non-limiting embodiment, the density of the particulate material may be at least 3.2 g/cm³ such as at least 3.5 g/cm³ or at least 3.8 g/cm³ or at least 4.0 g/cm³ or at least 4.2 g/cm³ or at least 4.5 g/cm³ or at least 4.8 g/cm³ or at least 5.0 g/cm³ or at least 5.2 g/cm³ or at least 5.5 g/cm³. In another non-limiting embodiment, the particulate material may have a density of not greater than 6.8 g/cm³ or not greater than 6.5 g/cm³ or not greater than 6.2 g/cm³ or not greater than 6.0 g/cm³ or not greater than 5.8 g/cm³ or not greater than 5.5 g/cm³. It will be appreciated that the density may be within a range including any of the minimum and maximum values noted above, including, for example, but not limited to at least 3.5 g/cm³ and not greater than 6.5 g/cm³ or within a range including at least 4 g/cm³ and not greater than 6 g/cm³ or within a range including at least 5 g/cm³ and not greater than 6 g/cm³.

In certain instances, the particulate may be relatively dense with little porosity. For example, the particulate may have a certain porosity that may facilitate improved performance of the composition, such as a porosity of not greater than 20 vol % for a total volume of the particulate, such as not greater than 15 vol % or not greater than 12 vol % or not greater than 10 vol % or not greater than 8 vol % or not greater than 5 vol % or not greater than 3 vol %, or not greater than 2 vol % or not greater than 1 vol % or not greater than 0.5 vol % or not greater than vol %. Still, in another non-limiting embodiment, the particulate may have a porosity of at least 0.1 vol % or at least 0.5 vol % or at least 1 vol % or at least 5 vol % or even at least 15 vol %. The porosity of the particulate material can be within a range including any of the minimum and maximum percentages noted above.

According to one embodiment, a plurality of abrasive particles may include at least one or a plurality of particulates described in any of the embodiments herein. The plurality of abrasive particles may include a minority content or a majority content of the particulates. In at least one instance, the plurality of abrasive particles includes at least 50 wt % or at least 60 wt % or at least 70 wt % or at least 80 wt % or at least 90 wt % or at least 95 wt % or at least 99 wt % particulates. In one instance, the plurality of abrasive particles consists entirely of the particulates. In another non-limiting embodiment, the plurality of abrasive particles includes a batch of abrasive particles that may be used for a material removal operation or incorporation into a fixed abrasive. According to one embodiment, the batch of abrasive particles may have a weight of at least 10 grams, but may include a greater weight of abrasive particles, including contents of kilograms or more.

In yet another aspect, a chemical mechanical planarization (CMP) slurry may include a carrier and a plurality of particles including the particulate of the embodiments herein including any one or more combinations of features of said particulate. The plurality of particles may include a plurality of abrasive particles including any of the features of the embodiments herein.

A CMP slurry may be formed according to the following non-limiting method. It will be appreciated that other additives in other contents can be used and the following process is merely illustrative of a CMP slurry according to one embodiment. The process for making a CMP slurry may include the steps of obtaining 10546 grams of deionized water and adding that to a mixing vessel. Adding 3809 grams of core-shell particles (e.g., abrasive particles) of the embodiments herein to the deionized wafer and mixing for approximately 10 minutes to create a first mixture. Adding 480 grams of tartaric acid and adding 8 grams of 1,2,4-Triazole to the first mixture and mixing for approximately 20 minutes to create a second mixture. Adding approximately 914 grams of hydrogen peroxide (H₂O₂) to the second mixture and mixing for approximately 5 minutes to create a CMP mixture. The pH of the CMP mixture can be adjusted to approximately 7.5 using KOH. The final CMP mixture includes approximately 2 wt % particulate material, 2 wt % H₂O₂, 3% tartaric acid, 0.05 wt % 1,2,4-Triazole.

The CMP slurry may include other additives besides the carrier and the plurality of particles. For example, in certain instances the CMP slurry may further include at least one of a surfactant, dispersant, wetting agent, thickener, defoamer, antimicrobial agent, suspension aid, stabilizer, lubricant, rheological modifier, or any combination thereof. For example, certain optional additives can include oxidizers, dispersants, surfactants, lubricants, or any combination thereof. Some suitable examples of oxidizers can include peroxides (e.g., H₂O₂), persulfides (e.g., H₂S₂), perchlorates (e.g., KClO₄), periodates (e.g., KIO₄), perbromates (e.g., KBrO₄), permanganate salts (e.g., KMnO₄, NaMnO₄), chromates (e.g., K₃CrO₈), ceric ammonium nitrates (e.g., (NH₄)₂Ce(NO₃)₆), ferrocyanides (e.g., K₄Fe(CN)₆), persulfates, or any combination thereof. Some suitable examples of dispersants include potassium hexametaphosphate, polyvinylpyrrolidone, potassium polynaphthalene sulfonate, potassium polymethacrylate, ammonium polymethacrylate, potassium polyacrylate, ammonium polyacrylate, potassium lignosulfonate. In some limited applications, a dispersant with sodium (e.g., any of the above listed dispersants) may be used, but is not typical in all applications (e.g., electronics industry). Some suitable examples of surfactants can include oleic acid, cetyltrimethylammonium bromide, dodecanthiol, oleylamine, sodium dodecyl sulfate, hydroxyl phosphono-acetic acid, or any combination thereof. Some suitable examples of lubricants can include fluorosurfactants, zinc stearate, manganese dioxide, molybdenum disulfide, aluminosilicates, organosilicone copolymers, or any combination thereof. In another embodiment, one or more optional complexing agents may be added (e.g., malonic acid, tartaric acid, citric acid, and amino acid). In another embodiment, an optional corrosion inhibitor may be added (e.g., BTA, triazole (e.g., 1, 2, 4-Triazole), phosphonic acid, etc.). The CMP slurry may include one or more of any of the foregoing additives.

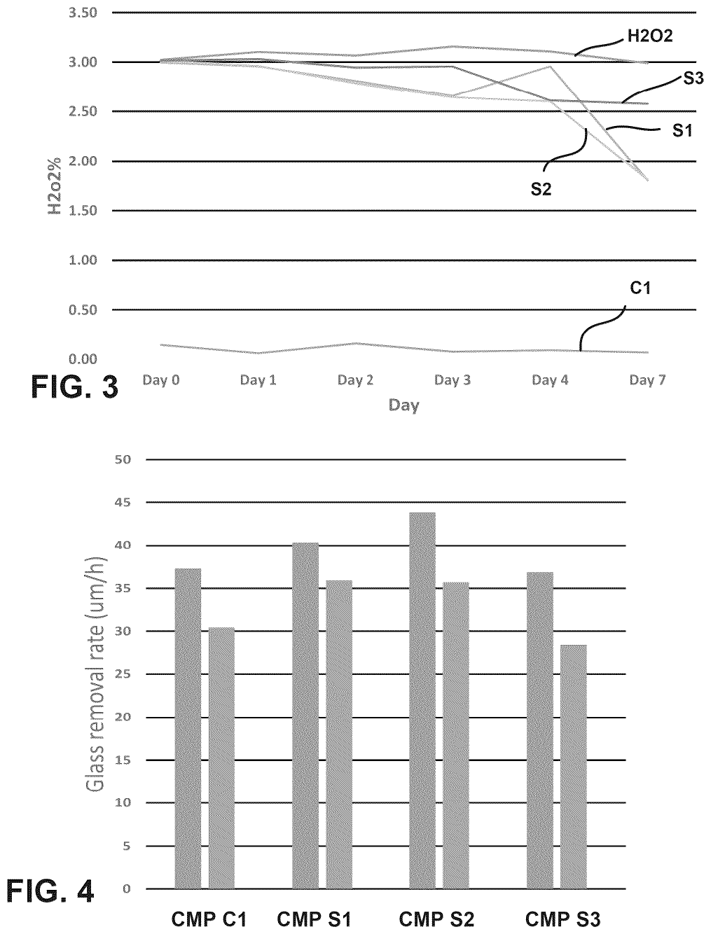

The CMP slurry can have a high stability with regard to the presence of hydrogen peroxide. In one embodiment, the Hydrogen Peroxide Stability % Reduction of the CMP slurry can be not greater than 50%. As used herein, the phrase “Hydrogen Peroxide Stability % Reduction” means the decrease in the hydrogen peroxide content of the slurry after seven days expressed in percent. As illustrated in FIG. 3, it can be seen that a CMP slurry containing plain zirconia particles which do not have a silica shell could not maintain any of the hydrogen peroxide even for one day, while with increasing thickness of the shell including silica, the H₂O₂ content of the CMP slurry could be maintained to a large extent. The CMP slurry of the present disclosure can combine using modified zirconia particles with desired advantages for polishing, while allowing a high stability of H₂O₂ contained in the slurry.

In certain other instances, a composition may be a dry or wet composition. A wet composition may include the CMP slurry including a liquid phase carrier that facilitates dispersion of the plurality of abrasive particles in the carrier. That is, the plurality of abrasive particles may be suspended in the liquid carrier to form the CMP slurry. After forming the dry powder composition, it may be shipped to a customer, and the customer may add a liquid carrier to create a polishing composition in the form of a slurry. However, in other instances, the dry powder composition can be dispersed within a liquid carrier prior to being sent to a customer. Some suitable examples of liquid carriers can include polar or non-polar liquid materials. In one embodiment, the carrier can include water, and may consist essentially of water, and more particularly, may consist essentially of deionized water.

The compositions of the embodiments can be used in various industries, and particularly, in the electronics industry for chemical mechanical planarization. In at least one embodiment, the CMP slurry may be used to finish a surface of a substrate having both metal and ceramic portions exposed. In one non-limiting embodiment, the CMP slurry containing the particulate material may be used on workpieces including materials such as dielectric materials (e.g., silica), nitrides (Si₃N₄, GaN), carbides (e.g., SiC), metal or metal alloys (e.g., W, Al, Cu, Co, Ta, Ru, Au). According to a particular embodiment, the particulates of the embodiments herein may be suitable for use in a CMP slurry configured for use in copper barrier polishing.

In one particular aspect, the CMP slurry may have a particularly small difference in the material removal rate between certain types of material. For example, the CMP slurry may have a ST Material Removal Rate Percent Difference of not greater than 300%, such as not greater than 200% or not greater than 100%. As used herein, the ST Material Removal Rate Percent Difference is the difference in the material removal rate of the CMP slurry of polishing a silica (SiO₂) substrate and a tantalum nitride (TaN) substrate.

As further demonstrated in the examples, the CMP slurry can have a high efficiency of polishing a substrate including copper (Cu). In a particular aspect, Cu material removal rate can be at least 1500 Å/min. In a certain particular aspect, the CMP slurry can have a removal rate for both a TaN material and a SiO₂ material of at least 100 Å/min and a copper removal rate of at least 1500 Å/min, while having a high stability for hydrogen peroxide.

Many different aspects and embodiments are possible. Some of those aspects and embodiments are described herein. After reading this specification, skilled artisans will appreciate that those aspects and embodiments are only illustrative and do not limit the scope of the present invention. Embodiments may be in accordance with any one or more of the embodiments as listed below.

### EMBODIMENTS

The embodiments include any one or more combinations of any features described herein.

Embodiment 1. A chemical mechanical planarization (CMP) slurry comprising:
a plurality of particles distributed in a carrier, wherein at least a portion of the particles of the plurality of particles have a body including a core comprising zirconia and a shell overlying at least a portion of the core, wherein the shell comprises silica; an oxidizing agent; and a carrier, wherein the CMP slurry comprises at least one of:
a Hydrogen Peroxide Stability % Reduction of not greater than 50%, the Hydrogen Peroxide Stability % Reduction being calculated according to [(% H₂O₂ at day zero−% H₂O₂ at day seven)/% H₂O₂ at day zero]×100%;
a SiO₂ material removal rate of at least 100 Å/min;
a Cu material removal rate of at least 1500 Å/min;
a TaN material removal rate of at least 100 Å/min;
a ST Material Removal Rate Percent Difference of not greater than 300%.

Embodiment 2. The CMP slurry of Embodiment 1, wherein the slurry comprises a combination of two or more of:
the Hydrogen Peroxide Stability % Reduction of not greater than 50%;
the SiO₂ material removal rate of at least 100 Å/min;
the Cu material removal rate of at least 1500 Å/min;
the TaN material removal rate of at least 100 Å/min; and
the ST Material Removal Rate Percent Difference of not greater than 300%.

Embodiment 3. The CMP slurry of Embodiment 2, wherein the slurry consists of a combination of each of:
the Hydrogen Peroxide Stability % Reduction of not greater than 50%;
the SiO₂ material removal rate of at least 100 Å/min;
the Cu material removal rate of at least 1500 Å/min;
the TaN material removal rate of at least 100 Å/min; and
the ST Material Removal Rate Percent Difference of not greater than 300%.

Embodiment 4. The CMP slurry of any one of the preceding Embodiments, wherein the Hydrogen Peroxide Stability % Reduction is not greater than 45% or not greater than 40% or not greater than 35% or not greater than 30% or not greater than 25% or not greater than 20% or not greater than 18% or not greater than 16% or not greater than 14% or not greater than 12% or not greater than 10% or not greater than 8% or not greater than 6% or not greater than 4%.

Embodiment 5. The CMP slurry of any one of the preceding Embodiments, wherein the Hydrogen Peroxide Stability % Reduction is at least 0.1%, or at least 0.5%, or at least 1%.

Embodiment 6. The CMP slurry of any one of the preceding Embodiments, wherein the SiO₂ material removal rate is at least 125 Å/min, or at least 150 Å/min, or at least 175 Å/min, or at least 200 Å/min, or at least 225 Å/min, according to the CMP Test.

Embodiment 7. The CMP slurry of any one of the preceding Embodiments, wherein the SiO₂ material removal rate is not greater than 600 Amin or not greater than 500 Å/min or not greater than 400 Å/min according to the CMP test conditions provided in Table 3.

Embodiment 8. The CMP slurry of any one of the preceding Embodiments, wherein the copper material removal rate is at least 1550 Å/min, or at least 1575 Å/min, or at least 1600 Å/min, or at least 1650 Å/min, or at least 1700 Å/min, or at least 1750 Å/min, according to the CMP test conditions provided in Table 3.

Embodiment 9. The CMP slurry of any one of the preceding Embodiments, wherein the copper material removal rate is not greater than 4000 Å/min, or not greater than 3000 Å/min, or not greater than 2500 Å/min, according to the CMP test conditions provided in Table 3.

Embodiment 10. The CMP slurry of any one of the preceding Embodiments herein wherein the TaN material removal rate is at least 125 Å/min, or at least 150 Amin, or at least 175 Å/min, or at least 200 Å/min, or at least 225 Å/min, or at least 250 Å/min, or at least 300 Å/min, as measured according to the CMP test conditions provided in Table 3.

Embodiment 11. The CMP slurry of any one of the preceding Embodiments, wherein the ST Removal Rate Percent Difference is not greater than 250% or not greater than 225% or not greater than 200% or not than 150% or not greater than 125% or not greater than 100%.

Embodiment 12. The CMP slurry of any one of the preceding Embodiments, wherein the core comprises at least 50 vol % zirconia for a total volume of the core, or at least 75 vol % zirconia, or at least 80 vol % zirconia, or at least 90 vol % zirconia, or at least 95 vol % zirconia, or at least 98 vol % zirconia or at least 99 vol % zirconia, or least 99.5 vol % zirconia, or consists essentially of zirconia, or wherein the core consists of zirconia.

Embodiment 13. The CMP slurry of any one of the preceding Embodiments, wherein the core comprises a polycrystalline abrasive particulate.

Embodiment 14. The CMP slurry of any one of the preceding Embodiments, wherein the shell comprises an average thickness of at least 0.5% and not greater than 20% based on an average (D50) size of the core, or at least 1% and not greater than 10%.

Embodiment 15. The CMP slurry of any one of the preceding Embodiments, wherein the shell comprises at least 90 vol % silica for a total volume of the shell, or at least 95 vol % silica, or at least 98 vol % silica, or consists essentially of silica, or consisting of silica.

Embodiment 16. The CMP slurry of any one of the preceding Embodiments, wherein the shell comprises not greater than 9 wt % impurities, or not greater than 7 wt % impurities, or not greater than 5 wt % impurities, or not greater than 2 wt % impurities, or not greater than 1 wt % impurities, or not greater than 0.5 wt % impurities.

Embodiment 17. The CMP slurry of any one of the preceding Embodiments, wherein the shell overlies at least 50% of the total surface area of the core, or at least 60%, or at least 70%, or at least 80%, or at least 90%, or at least 95%, or at least 99%.

Embodiment 18. The CMP slurry of any one of the preceding Embodiments, wherein the shell comprises an average thickness of at least 1 nm, or at least 3 nm, or at least 5 nm, or at least 6 nm, or at least 7 nm, or at least 8 nm, or at least 9 nm, or at least 10 nm, or at least 15 nm.

Embodiment 19. The CMP slurry of any one of the preceding Embodiments, wherein the shell comprises an average thickness of not greater than 45 nm, or not greater than 40 nm, or not greater than 35 nm, or not greater than 30 nm, or not greater than 25 nm, or not greater than 20 nm, or not greater than 18 nm, or not greater than 15 nm, or not greater than 14 nm, or not greater than 13 nm, or not greater than 12 nm.

Embodiment 20. The CMP slurry composition wherein the shell comprises an average thickness of at least 4 nm and not greater than 20 nm.

Embodiment 21. The CMP slurry of any one of the preceding Embodiments, wherein each particle of the plurality of particles includes the core comprising zirconia and the shell comprising silica.

Embodiment 22. The CMP slurry of any one of the preceding Embodiments, wherein an average particles size of the plurality of particles is at least 30 nm, or at least 50 nm, or at least nm, or at least 90 nm, or at least 100 nm, or at least 120 nm, or at least 150 nm, or at least 170 nm.

Embodiment 23. The CMP slurry of any one of the preceding Embodiments, wherein an average particles size of the plurality of particles is not greater than 500 nm, or not greater than 400 nm, or not greater than 300 nm, or not greater than 250 nm, or not greater than 200 nm.

Embodiment 24. The CMP slurry of any one of the preceding Embodiments, wherein an average particle size (D50) of the plurality of particles is within a range of at least 50 nm to not greater than 300 nm.

Embodiment 25. The CMP slurry of any one of the preceding Embodiments, wherein an amount of the plurality of particles is at least 1 wt % based on the total weight of the CMP slurry, or at least 1.5 wt %, or at least 2 wt %, or at least 3 wt %, or at least 5 wt %.

Embodiment 26. The CMP slurry of any one of the preceding Embodiments, wherein an amount of the plurality of particles is not greater than 10 wt % based on the total weight of the CMP slurry, or not greater than 8 wt %, or not greater than 6 wt %, or not greater than 4 wt %.

Embodiment 27. The CMP slurry of any of the preceding Embodiments, wherein a pH of the CMP slurry is at least 2.5, or at last 3.0, at least 3.5, at least 4.0, at least 4.5, at least 5.0, or at least 5.5, or at least 6.0, or at least 6.5, or at least 7.0, or at least 7.5, or at least 8.0.

Embodiment 28. The CMP composition or any one of the preceding Embodiments, wherein a pH of the CMP slurry is not greater than 10, or not greater than 9, or not greater than 8, or not greater than 7, or not greater than 6.5, or not greater than 6, or not greater than 5.5, or not greater than 5.

Embodiment 29. The CMP slurry of Embodiments 26 or 27, wherein the pH is in a range between 5 and 8.

Embodiment 30. The CMP slurry of any one of the preceding Embodiments, further comprising an oxidizing agent, a complexing agent, a corrosion inhibitor, a pH adjuster, or any combination thereof.

Embodiment 31. The CMP slurry of Embodiment 30, wherein the oxidizing agent includes a peroxide, a persulfate, or a permanganate salt.

Embodiment 32. The CMP slurry of Embodiment 31, wherein the oxidizing agent includes hydrogen peroxide (H₂O₂).

Embodiment 33. The CMP slurry of any one of the preceding Embodiments, wherein an amount of the oxidizing agent is at least 0.5 wt % based on the total weight of the slurry, or at least 1 wt %, or at least 1.5 wt %, or at least 2.0 wt %, or at least 3.0 wt %, or at least 5 wt %, or at least 7 wt %.

Embodiment 34. The CMP slurry of any one of the preceding Embodiments, wherein an amount of the oxidizing agent is not greater than 15 wt % based on the total weight of the slurry, or not greater than 10 wt %, or not greater than 5 wt %.

Embodiment 35. The CMP slurry of Embodiment 30, wherein the complexing agent includes malonic acid, tartaric acid, citric acid, amino acid, or any combination thereof.

Embodiment 36. The CMP slurry of Embodiment 30, wherein the corrosion inhibitor includes a benzotriazole (BTA), triazole, phosphonic acid, or any combination thereof.

Embodiment 37. The CMP slurry of any one of the preceding Embodiment, wherein the carrier includes water.

Embodiment 38. A method of polishing a substrate comprising: providing a substrate and a CMP slurry; and polishing the substrate with the CMP slurry using a polishing pad; wherein the CMP slurry comprises a plurality of particles distributed in a carrier, and oxidizing agent, and a carrier, wherein at least a portion of the particles of the plurality of particles have a body including a core comprising zirconia and a shell overlying at least a portion of the core, the shell comprises silica.

Embodiment 39. The method of Embodiment 38, wherein the substrate includes a ceramic material, a metal, a metal alloy, diamond, a polymer, a group III-V compound, or a group IV-IV compound.

Embodiment 40. The method of Embodiment 39, wherein the substrate includes a dielectric material, a nitride, a carbide, a metal, or a metal alloy.

Embodiment 41. The method of Embodiments 39 or 40, wherein the substrate includes copper, silica, tantalum nitrate (TaN), or any combination thereof.

Embodiment 42. The method of any one of Embodiments 38-40, wherein the method is configured for copper barrier polishing.

Embodiment 43. The method of any one of Embodiment 38-42, wherein the method further comprises adjusting a pH of the CMP slurry before the polishing.

Embodiment 44. The method of any one of Embodiments 38-43, wherein a pH of the CMP slurry is at least 2.5, or at last 3.0, at least 3.5, at least 4.0, at least 4.5, at least 5.0, or at least 5.5, or at least 6.0, or at least 6.5, or at least 7.0, or at least 7.5, or at least 8.0.

Embodiment 45. The method of any one of Embodiments 38-44, wherein a pH of the CMP slurry not greater than 10, or not greater than 9, or not greater than 8, or not greater than 7, or not greater than 6.5, or not greater than 6, or not greater than 5.5, or not greater than 5.

Embodiment 46. The method of any one of Embodiments 38-45, wherein the at least one oxidizing agent includes a peroxide, a persulfate, a permanganate, chlorite, a nitrite, a perchlorate, a hypochlorite, manganese oxide, or any combination thereof.

Embodiment 47. The method of any one of Embodiments 38-46, wherein the oxidizing agent includes a peroxide, a persulfate, a permanganate salt, or a combination thereof.

Embodiment 48. The method of any one of Embodiments 38-47, wherein the oxidizing agent includes hydrogen peroxide (H₂O₂).

Embodiment 49. The method of any one of Embodiments 38-48, wherein a SiO₂ material removal rate is at least 100 Å/min, or at least 125 Å/min, or at least 150 Å/min, or at least 175 Å/min, or at least 200 Å/min, or at least 225 Å/min, according to the CMP Test.

Embodiment 50. The method of any one of Embodiments 38-48, wherein a SiO₂ material removal rate is not greater than 600 Å/min or not greater than 500 Å/min or not greater than 400 Å/min according to the CMP Test.

Embodiment 51. The method of any one of Embodiments 38-50, wherein a copper material removal rate is at least 1500 Å/min, or at least 1550 Å/min, or at least 1575 Å/min, or at least 1600 Å/min, or at least 1650 Å/min, or at least 1700 Å/min, or at least 1750 Å/min, according to the CMP Test.

Embodiment 52. The method of any one of Embodiments 38-51, wherein the copper material removal rate is not greater than 4000 Å/min, or not greater than 3000 Å/min, or not greater than 2500 Å/min, according to the CMP Test.

Embodiment 53. The method of any one of Embodiments 38-52, wherein a TaN material removal rate is at least 100 Å/min, or at least 125 Å/min, or at least 150 Å/min, or at least 175 Å/min, or at least 200 Å/min, or at least 225 Å/min, or at least 250 Å/min, or at least 300 Å/min, as measured according to the CMP Test.

Embodiment 54. The method of any one of Embodiments 38-53, wherein a ST Removal Rate Percent Difference is not greater than 300%, or not greater than 250%, or not greater than 225% or not greater than 200% or not than 150% or not greater than 125% or not greater than 100%.

Embodiment 55. The method of any one of Embodiments 38-54, wherein an average particles size of the plurality of particles is at least 30 nm, or at least 50 nm, or at least 70 nm, or at least 90 nm, or at least 100 nm, or at least 120 nm, or at least 150 nm, or at least 170 nm.

Embodiment 56. The method of any one of Embodiments 38-55, wherein an average particles size of the plurality of particles is not greater than 500 nm, or not greater than 400 nm, or not greater than 300 nm, or not greater than 250 nm, or not greater than 200 nm.

Embodiment 57. The method of any one of Embodiments 38-56, wherein an average particle size (D50) of the plurality of particles is within a range of at least 50 nm to not greater than 300 nm.

Embodiment 58. The method of any one of Embodiments 38-57, wherein the shell comprises an average thickness of at least 1 nm, or at least 3 nm, or at least 5 nm, or at least 6 nm, or at least 7 nm, or at least 8 nm, or at least 9 nm, or at least 10 nm, or at least 15 nm.

Embodiment 59. The method of any one of Embodiments 38-58, wherein the shell comprises an average thickness of not greater than 45 nm, or not greater than 40 nm, or not greater than 35 nm, or not greater than 30 nm, or not greater than 25 nm, or not greater than 20 nm, or not greater than 18 nm, or not greater than 15 nm, or not greater than 14 nm, or not greater than 13 nm, or not greater than 12 nm.

Embodiment 60. The method of any one of Embodiments 38-59, wherein the average (D50) particle size of the plurality of particles ranges from 100 nm to 250 nm, and a thickness of the shell ranges from 3 nm to 20 nm, or from 5 nm to 15 nm.

### EXAMPLES

### Example 1

The following non-limiting examples illustrate the present invention.

A zirconia raw material particular for use as the core was obtained from Saint-Gobain as Product Code 9839/9840, which may also be referred to as Zirpol Nano. The particle size distribution features of the particles are provided in Table 1.

TABLE 1

| | Sample S1: Uncoated Core |
|---|---|
| D50 [nm] | 175 |
| (D100-D0)/D50 | 1.71 |
| (D90-D10)/D50 | 0.62 |

After obtaining the core material, it was treated to form a silica shell overlying at least a portion of the core. The process for forming the shell included a deposition process. The process for forming the shell on the core particulate included using a silicon-containing source, such as an organic silicon source (e.g., TMOS, TEOS) to form the silica coating. The organic silicon source was added to water to cause the release of the silicon material. The core particles were added to the water and the silicon source to create a mixture. The pH of the mixture can be adjusted to control the deposition of the silicon source onto the surface of the core particles, such that a particulate material having a core zirconia core and a silica shell structure is created.

The coated particles of Sample S1 were formed such that the shell had an average thickness of approximately 1 nm.

### Example 2

A sample of particulates having a core-shell structure was formed according to the process of Example 1, except that the shell was formed to have an average thickness of approximately 3 nm.

### Example 3

A sample of particulates having a core-shell structure was formed according to the process of Example 1, except that the shell was formed to have an average thickness of approximately 12 nm.

### Example 4

Samples S1, S2, and S3 were tested for H₂O₂ compatibility according to the following test procedure:

Of the particulate material sample, 0.4 g was weighed (to ±0.001 g) and recorded as Wg. 150 mL of sulfuric acid (1:19) was measured into a 500 mL Erlenmeyer flask and cooled down below 10° C. using a laboratory refrigerator or freezer. When the temperature of the solution was below 10° C., about three drops of ferroin indicator solution were added and then titrated with ceric ammonium nitrate solution (0.1N) contained in a burette until the indicator changed to a blue color. Thereafter, the 0.4 g measured sample of the particulate material was added to the cold solution. As calculated from grams of sample=(40 mL×0.1N×1.701)/% C where % C is the estimated concentration of hydrogen peroxide and 1.701 is the weight per milliequivalent of hydrogen peroxide×100, and swirl to mix. It was rapidly titrated with ceric ammonium nitrate solution (0.1N) to the same blue color. The titration result, mL Ce+3, is calculated by subtracting the final volume of ceric ammonium nitrate used from the initial volume. The sample percent concentration of hydrogen peroxide was calculated using the following equation: % Concentration of H₂O₂=(ml Ce+3)×(N Ce+3)×1.701/grams of sample.

### Example Calculation

Titrant volume:40.49 mL final−1.52 mL initial=38.97 mL titrant

% Concentration of H₂O₂: (38.97 mL Ce+3×0.0950 mol·eq./L Ce+3×1.701)/17.80 g sample=0.3538%

FIG. 3 includes a plot of H₂O₂% over time (days 0-7) to evaluate the stability and compatibility of the Samples S₁, S₂, and S₃, and of uncoated zirconia particles (Sample C1), and of a 3% H₂O₂ solution. As demonstrated, Samples S₁, S₂, and S₃ had better compatibility and stability with H₂O₂ as compared to Sample C1. Sample S₁ had an approximate Hydrogen Peroxide Stability % Reduction of 40% as calculated from % H₂O₂ at day zero of 3% and a % H₂O₂ at day 7 of 1.8%. Thus, [(3.0−1.8)/3.0]×100%=40%. Sample S₂ had an approximate Hydrogen Peroxide Stability % Reduction of 40% as calculated from % H₂O₂ at day zero of 3% and a % H₂O₂ at day 7 of 1.8%. Thus, [(3.0−1.8)/3.0]×100%=40%. Sample S₃ had an approximate Hydrogen Peroxide Stability % Reduction of 15% as calculated from % H₂O₂ at day zero of 3% and a % H₂O₂ at day 7 of 2.55%. Thus, [(3.0−2.55)/3.0](100%=15%.

The best H₂O₂ stability with time had Sample S₃, with the thickest silica coating of 6 nm.

Experiments are conducted with respective slurries comprising zirconia particles having a silica shell thickness of 9 nm and 12 nm, which show an even better H₂O₂ stability with time (lower H₂O₂ stability % reduction).

### Example 5

Samples S₁, S₂, and S₃ were tested as CMP slurries to evaluate their material removal rate on a glass substrate.

CMP slurries were created using the particulates from Samples S₁, S₂, and S₃, and the CMP slurry samples are referred to herein as CMP S₁, CMP S₂, and CMP S₃, respectively. Each of the CMP slurries was prepared by adding 1870 grams of deionized water to a mixing vessel. Thereafter, 1.2 grams of polyalkyleneoxide modified heptamethyltrisiloxane was added to the deionized water and mixed for approximately 5 minutes to create a first mixture. 120 grams of core-shell particles (e.g., abrasive particles of S₁, S₂, or S₃) were then added to the first mixture and mixed for approximately 30 minutes to create one of the representative CMP mixtures of CMP S₁, CMP S₂, and CMP S₃. The pH of each of the CMP mixtures was adjusted to approximately 5.5 using nitric acid. Each of the samples included approximately 1.5 wt % particulate material and 0.05 wt % polyalkyleneoxide modified heptamethyltrisiloxane.

Each CMP sample was tested two times according to the conditions provided in Table 2.

TABLE 2

| Machine: | SpeedFam GPAW 36″ | |
|---|---|---|
| Pad: | Suba X | |
| Substrate: | Glass | |
| Downforce: | 2 | psi |
| Platen Speed (RPM): | 40 | |
| Slurry flow rate: | 100 | ml/min |
| Polishing time: | 10 | min |

The results of the glass polishing tests is shown in FIG. 4, illustrating the glass removal rate for both of the tests for each sample.

### Example 6

Three new abrasive particulate samples (i.e., Samples S4, S5, and S6) were created according to the process of Example 1, except that the average thickness of each of the samples was adjusted. Sample S4 had an average shell thickness of 3 nm. Sample S5 had an average shell thickness of 6 nm. Sample S6 had an average shell thickness of 9 nm. Each sample of abrasive particulate was used to create three new CMP slurries, which were CMP S4, CMP S5, and CMP S6, respectively. The CMP slurries were formed according to the following procedure. To begin, 1950 grams of core-shell particles (e.g., abrasive particles of Sample S4, S5, or S6) were added to 5214 grams of deionized water and mixed for approximately 15 minutes to create a first mixture. Thereafter, 240 grams of tartaric acid was added to the first mixture and mixed for approximately 15 minutes to create a second mixture. Adding approximately 4 grams of 1,2,4-Triazole was then added to the second mixture and mixed for approximately 15 minutes to create a third mixture. Adding approximately 457 grams of hydrogen peroxide (H₂O₂) was then added to the third mixture and mixed for approximately 5 minutes to create one of the CMP samples CMP S4, CMP S5, or CMP S6. The pH of each of the CMP samples was adjusted to approximately 7-8 using KOH. Each of the CMP samples included approximately 2 wt % particulate material (S4, S5, or S6), 2 wt % H₂O₂, 3% tartaric acid, and 0.05 wt % 1,2,4-Triazole.

The polishing efficiency of the CMP samples was tested using as substrates copper wafers, TaN wafers, and silica wafers having a diameter of 6 inches. Each CMP slurry was tested twice on each substrate wafer type, according to the conditions provided in Table 3, which is herein also called “the CMP Test.” For the copper polishing, copper wafers from Advantive Technologies with lot #GM033018-1 were used, having an upper copper layer of 15,000 Å; for the TaN polishing, TaN wafers from Advantive Technologies, lot #GM111819-6, having an upper TaN layer of 3000 Å; and for the silicon dioxide polishing silicon oxide wafers from Advantive Technologies, lot #349547-1, with a thickness of 20,000 Å.

TABLE 3

| Machine: | IPEC 472 | |
|---|---|---|
| Pad: | IC1000 A2 | |
| Conditioning Disk: | Kinik (O-Pyradia, 350 Tips) | |
| Platen Diameter: | 22.5 | inches |
| Run Time: | 1 | min |
| Down force: | 3 | psi |
| Platen Speed: | 103 | rpm |
| Slurry flow rate: | 180 | ml/min |
| Carrier Speed: | 97 | rpm |

The material removal rates were measured according to the following techniques:

For the copper wafers, the material removal rate of the CMP slurry was calculated by using a 4-point probe from CDE ResMap 178. The thickness was calculated from the sheet resistance and resistivity of the metal across 49 points throughout the wafer. Measurements are taken before and after conducting the CMP test. The difference between the before and after measurements is the metal removal divided by the polishing time to yield the material removal rate.

For the TaN wafers, the removal rate was measured from the weight loss, area of the wafer, and density. The TaN weight of the wafer is measured before and after the CMP test. The change in the weight, area of the wafer, and the density are then used to calculate the material removal rate over the time of the test. For the Oxide wafer, the material removal rate of the CMP slurry is measured with Filmetrics F20 instrument. It uses an integrated spectrometer/light source unit to measure the thickness of the wafer across 7 points through the center of the wafer. This is done both before and after polishing. The difference is the metal removal divided by the polishing time to yield the metal removal rate.

For the silicon oxide wafers, the material removal rate was measured with a Filmetrics F20 instrument. It uses an integrated spectrometer/light source unit to measure the thickness of the wafer across 7 points through the center of the wafer. This was done both before and after polishing. The difference is the metal removal divided by the polishing time to yield the glass removal rate.

The results of the material removal rates for each of the CMP Samples CMP S4, CMP S5, and CMP S6 are summarized in Table 4.

TABLE 4

| | Thickness of | | | |
|---|---|---|---|---|
| CMP | SiO₂ shell | Cu | TaN | SiO₂ |
| Sample | [nm] | RR(Å/min) | RR(Å/min) | RR(Å/min) |
| CMP S4 | 3 | 1848 | 338 | 280 |
| CMP S5 | 6 | 1716 | 270 | 208 |
| CMP S6 | 9 | 1671 | 190 | 172 |

From the data shown in Table 4, the ST Material Removal Rate Percent Difference between the polishing of the silica wafers and the TaN wafers was calculated: For CMP sample S4 a value of 20% was calculated, for CMP sample S5 a value of 30%, and for CMP sample S6 a value of 10%.

It can be further seen from the data of Table 4 that with increasing thickness of the shell, the removal rate for copper, TaN, and SiO₂ decreases.

Experiments of slurry composition having a shell thickness of 12 nm, 15 nm, and 20 nm are conducted and confirm this trend.

Not to be bound to theory, a particular range of the silica coating thickness in relation to the zirconia core can have advantages with regard to obtaining a desired material removal rate and having a stable polishing slurry from the aspect of the H₂O₂ degradation.

The above-disclosed subject matter is to be considered illustrative, and not restrictive, and the appended claims are intended to cover all such modifications, enhancements, and other embodiments, which fall within the true scope of the present invention. Thus, to the maximum extent allowed by law, the scope of the present invention is to be determined by the broadest permissible interpretation of the following claims and their equivalents, and shall not be restricted or limited by the foregoing detailed description.

The Abstract of the Disclosure is provided to comply with Patent Law and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all features of any of the disclosed embodiments. Thus, the following claims are incorporated into the Detailed Description, with each claim standing on its own as defining separately claimed subject matter.

What is claimed is:

1. A chemical mechanical planarization (CMP) slurry comprising:
a plurality of particles distributed in a carrier, wherein at least a portion of the particles of the plurality of particles have a body including a core comprising zirconia and a shell overlying at least a portion of the core, wherein the shell comprises silica;
an oxidizing agent; and
a carrier,
wherein the CMP slurry comprises at least one of:
a Hydrogen Peroxide Stability % Reduction of not greater than 50%;
a SiO₂ material removal rate of at least 100 Å/min;
a Cu material removal rate of at least 1500 Å/min;
a TaN material removal rate of at least 100 Å/min; or
a ST Material Removal Rate Percent Difference of not greater than 300%.

2. The CMP slurry of claim 1, wherein the ST Removal Rate Percent Difference is not greater than 100%.

3. The CMP slurry of claim 1, wherein the core comprises at least 80 vol % zirconia for a total volume of the core.

4. The CMP slurry of claim 1, wherein the shell comprises an average thickness of at least 1% and not greater than 10% based on an average (D50) size of the core.

5. The CMP slurry of claim 1, wherein the shell comprises at least 90 vol % silica for a total volume of the shell.

6. The CMP slurry of claim 1, wherein the shell comprises an average thickness of at least 1 nm and not greater than 20 nm.

7. The CMP slurry of claim 1, wherein the shell comprises an average thickness of at least 4 nm and not greater than 15 nm.

8. The CMP slurry of claim 1, wherein an average particles size of the plurality of particles is at least 50 nm and not greater than 500 nm.

9. The CMP slurry of claim 1, wherein an amount of the plurality of particles is at least 1 wt % and not greater than 10 wt %.

10. The CMP slurry of claim 1, wherein the pH is in a range between 5 and 9.

11. The CMP slurry of claim 1, wherein the oxidizing agent includes a peroxide, a persulfate, a permanganate salt, or a combination thereof.

12. The CMP slurry of claim 1, wherein the oxidizing agent includes hydrogen peroxide (H₂O₂).

13. The CMP slurry of claim 1, wherein the carrier includes water.

14. The CMP slurry of claim 1, wherein an average (D50) particle size of the plurality of particles ranges from 100 nm to 250 nm, and a thickness of the shell ranges from 1 nm to nm.

15. A method of polishing a substrate comprising:
providing a substrate and a CMP slurry; and
polishing the substrate with the CMP slurry using a polishing pad,
wherein the CMP slurry comprises a plurality of particles distributed in a carrier, an oxidizing agent, and a carrier, wherein at least a portion of the particles of the plurality of particles have a body including a core comprising zirconia and a shell overlying at least a portion of the core, the shell comprising silica.

16. The method of claim 15, wherein the oxidizing agent includes hydrogen peroxide.

17. The method of claim 15, wherein a copper material removal rate is at least 1500 Å/min, according to the CMP Test.

18. The method of claim 15, wherein a TaN material removal rate is at least 100 Amin according to the CMP Test.

19. The method of claim 15, wherein a SiO₂ material removal rate is at least 100 Å/min according to the CMP Test.

20. The method of claim 15, wherein a ST Removal Rate Percent Difference is not greater than 100%.
